(19) United States
(12) Patent Application Publication
(10) Pub. No.: US 2023/0212746 A1
(43) Pub. Date: Jul. 6, 2023

(54) ROLL-TO-ROLL VAPOR DEPOSITION APPARATUS AND METHOD

(71) Applicant: 3M INNOVATIVE PROPERTIES COMPANY, St. Paul, MN (US)

(72) Inventors: Cedric Bedoya, Woodbury, MN (US); Brandon R. Pietz, St. Paul, MN (US); Tarris A. Sveback, New Richmond, WI (US); Joseph C. Spagnola, Woodbury, MN (US)

(21) Appl. No.: 18/000,430

(22) PCT Filed: May 4, 2021
(86) PCT No.: PCT/IB2021/053759

§ 371 Date: Dec. 1, 2022

Related U.S. Application Data
(60) Provisional application No. 63/037,286, filed on Jun. 10, 2020.

(51) Int. Cl. C23C 16/455; C23C 16/46; C23C 16/54; C23C 16/452; C23C 16/40

(52) U.S. Cl. CPC C23C 16/45551; C23C 16/405; C23C 16/452; C23C 16/463; C23C 16/545; C23C 16/45536

(57) ABSTRACT

A system. The system may include a first zone into which a first precursor is introduced; a second zone into which a second precursor is introduced; a third zone between the first zone and the second zone and in which a reactive species is generated; a fourth zone between the first zone and the third zone; a fifth zone between the second zone and the third zone; wherein a process gas is introduced into the fourth zone and the fifth zone; wherein the reactive species and the first precursor is mixed in the fourth zone and the reactive species and the second precursor is mixed in the fifth zone; and a substrate transport mechanism.

### BACKGROUND

Atomic layer deposition (“ALD”), formerly known as atomic layer epitaxy (“ALE”), is a thin film deposition process suited to deposit conformal coating in high aspect ratio features. Chemical vapor deposition (“CVD”) on the other hand shows higher deposition rate than ALD but with limited conformality performance. Developing a thin film coating method that can combine high conformality and high deposition rate will help the manufacturing development of a R2R process for metamaterials. While the preparation of the thin film coating are known, there are needs for a better process and system to make the thin film.

### SUMMARY

The present disclosure relates to a roll-to-roll vapor deposition system and a method of making a conformal metal oxide coating at high speed. The system and method of the current disclosure can enable a very high deposition rate on a wide variety of substrates.

In a first aspect, a system is provided. The system may include a first zone into which a first precursor is introduced; a second zone into which a second precursor is introduced; a third zone between the first zone and the second zone and in which a reactive species is generated; a fourth zone between the first zone and the third zone; a fifth zone between the second zone and the third zone; wherein a process gas is introduced into the fourth zone and the fifth zone; wherein the reactive species and the first precursor is mixed in the fourth zone and the reactive species and the second precursor is mixed in the fifth zone; and a substrate transport mechanism.

In another aspect, a method is provide. The method may include transporting the substrate over the first and the second support rollers; repeating the following sequence of steps to form a thin film on the substrate: (a) exposing the substrate to a precursor; (b) exposing the substrate to a mixture of a reactive species and a precursor; and (c) exposing the substrate to a plasma and a reactive species.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1 shows a schematic cross-sectional view of one embodiment, illustrating a system and method for roll-to-roll vapor deposition;

FIG. 2 shows the cross-sectional SEM image of Example 1.

FIG. 3 shows the cross-sectional SEM image of Example 2.

FIG. 4 shows the cross-sectional SEM image of Example 3.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should understood that:

The terms “about” or “approximately” with reference to a numerical value or a shape means +/-five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification, the recitation of numerical ranges by endpoints includes all numbers subsumed within that range (e.g. 1 to 5 includes 1, 1.5, 2, 2.75, 3, 3.8, 4, and 5).

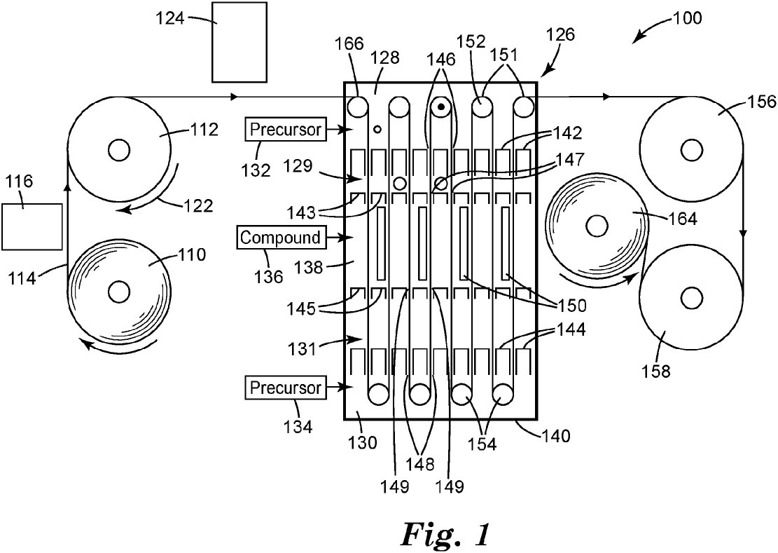

FIG. 1 is a diagram of a system 100, illustrating a process for making a conformal metal oxide coating at high deposition rate. System 100 can be contained within an inert environment and can include an unwinder roller 110 for paying out a substrate 114 from an input roll of the substrate 114. System 100 can include drum 112 for receiving and moving providing a moving web. A optional substrate pretreating source 116 can provide a treatment of the surface the substrate 114, for example, supplying a plasma to substrate 114. Drum 112 can advance the substrate 114 in a direction shown by arrow 122. In some embodiments, system 100 may further include a heating system 124 to heat the substrate 114 before the deposition of a thin film onto the substrate. Heating system 124 useful in the systems of the present disclosure include one or more of, for example, an infrared radiation heating source, a heated drum, a conductive heating source and inductive heaters. In some embodiments, the substrate 114 can be heated to a range of 50 to 150° C. In some embodiments, the substrate 114 can be heated to a range of 70 to 100° C. In some embodiments, the substrate 114 can be heated to 100° C. In some embodiments, the substrate 114 can be heated to 80° C.

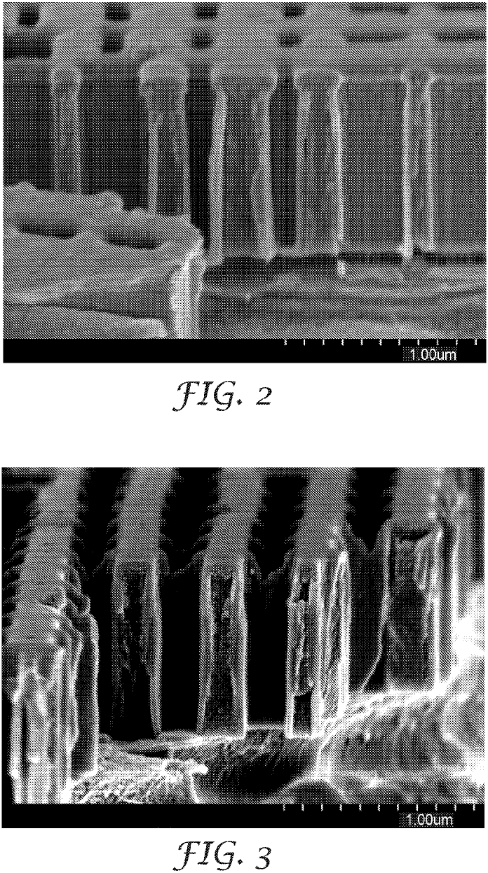

After the substrate 114 is heated, the substrate 114 is advanced into an coating system 126 for the deposition a thin film onto the substrate 114. With reference to FIG. 2, the coating system 126 includes first and second precursor zones 128, 130, respectively, and a third zone 138 in which a reactive species is generated. The coating system 126 further includes a fourth zone 129 between the first zone 128 and the third zone 138 and a fifth zone 131 between the second zone 130 and the third zone 138. When in use, reactive first and second precursor gases (Precursor 1 and Precursor 2) are introduced into the respective first and second precursor zones 128, 130 from first and second precursor delivery systems 132, 134. Precursor delivery systems 132, 134 may include precursor source containers (not shown) located outside or within precursor zones 128, 130. Additionally or alternatively, precursor delivery systems 132, 134 may include piping, pumps, valves, tanks, and other associated equipment for supplying precursor gases into precursor zones 128, 130. A compound delivery system 136 is similarly included for injecting a compound into a third zone 138 to generate reactive species. In the embodiment shown in FIG. 1, precursor zones 128, 130 and third zone 138 are defined and bordered by an outer reaction chamber housing or vessel 140, divided by first and second dividers 142, 144. Coating system 126 may include additional zones, for example, the fourth zone 129 (a first mixing zone) between precursor zone 128 and zone 138, divided by first and third dividers 142, 143. And Coating system 126 may include the fifth zone 131 (a second mixing zone) between precursor zone 130 and the third zone 138, divided by second and fourth dividers 144, 145. The fourth zone 129 and fifth zone 131 (the first and second mixing zones) may include piping, pumps, valves, tanks, and other associated equipment for allowing the mixing and transport of gasses. A series of first passageways 146 through first divider 142 are spaced apart along a general direction of travel of substrate 114, and a corresponding series of second passageways 148 are provided through second divider 144. The passageways 146, 147, 148, 149 are arranged and configured for substrate 114 to be threaded therethrough back and forth between first and second precursor zones 128, 130 multiple times, and each time through the third zone 138, fourth zone 129 and the fifth zone 131. For a web substrate, passageways 146, 147, 148, 149 preferably comprise slits having a width (exaggerated in FIG. 1) that is slightly greater than the thickness of substrate 114 and a length (not shown) extending into the plane of FIG. 1 (i.e., normal to the page) and that is slightly greater than a width of the substrate. The third zone 138 is, thus, preferably separated (albeit imperfectly) from the first precursor zone 128 by first divider 142 and from second precursor zone 130 by second divider 144.

A series of plasma or other free radical-generating generators 150 is operably associated with the third zone 138, wherein the free radical generators 150 operating at 50 W to 1500 W generate reactive species from the compound 136. Radical generators 150 may include a radio-frequency (RF) plasma generator, microwave plasma generator; direct-current (DC) plasma generator, alternative-current (AC) plasma generator or UV light source, and preferably continuously generates a population of radical species in-situ within third zone 138 by means of a plasma, for example. In some embodiments, radical generators 150 are positioned in third zone 138 so that only one surface of substrate 114 may contact reactive species. Reactive species can include, but is not limited to, activated oxygen, ozone, water, activated nitrogen, ammonia and activated hydrogen. In some embodiments, reactive species can be generated by applying energy to chemical compound 136, for example, cracking a dry, oxygen-containing compound so as to generate the activated oxygen species. In some of such embodiments, a plasma generator (e.g., a DC plasma source, an RF plasma source, or an inductively-coupled plasma source) may energize and decompose a dry gaseous oxygen-containing compound (for example dry air, O₂, CO₂, CO, NO, NO₂, or mixtures of two or more of the foregoing, with or without added nitrogen (N₂) and/or another suitable inert carrier gas). In some other embodiments, an oxygen-containing compound, for example, hydrogen peroxide, water, or a mixture thereof, may be decomposed or cracked via non-plasma activation (e.g., a thermal process). In still other embodiments, ozone may be generated (e.g., via corona discharge) remotely or proximal to the substrate or substrate path so that ozone is supplied to the substrate surface. In some embodiments, reactive species can be generated by introducing a chemical compound into a plasma.

In some embodiments, a first precursor is supplied into precursor zone 128. As the substrate 114 enters the first precursor zone 128, a surface 166 of the substrate 114 is exposed to the first precursor 132 so that the first precursor 132 is chemisorbed to the substrate surface, leaving a chemisorbed species at the surface that is reactive with reactive species. Following deposition of the first precursor on the substrate 114, the substrate 114 then enters the fourth zone 129 (the first mixing zone), which in some embodiments is supplied with a mixture of the precursor 132 and reactive species. Following exposure to the mixture of the precursor 132 and reactive species, the substrate 114 then enters the third zone 138, which in some embodiments is supplied reactive species generated in a plasma formed from compound 136. Following exposure to the plasma and reactive species generated in 138, the substrate 114 then enters the fifth zone 131 (the second mixing zone) which in some embodiments is supplied with a mixture of the precursor 134 and reactive species.

A second precursor 134 enters precursor zone 130. The substrate 114 enters precursor zone 130 and is exposed to the second precursor 134. The substrate 114 then traverses the fifth zone 131 (the second mixing zone), third zone 138, the fourth zone 129 (the first mixing zone) and precursor zone 128 a predetermined number of additional times before a thin film is formed on the substrate 114. In some embodiments, the substrate 114 then traverses the fifth zone 131 (the second mixing zone), third zone 138, the fourth zone 129 (the first mixing zone) and precursor zone 128 between 2 or more additional times to form a thin film substrate 114. In some embodiments, the substrate 114 then traverses the fifth zone 131 (the second mixing zone), third zone 138, the fourth zone 129 (the first mixing zone) and precursor zone 128 between 2 to 5 additional times to form a thin film substrate 114.the thin film may have a thickness of no more than ^{obj} 250 nm, no more than 200 nm, no more than 150 nm, no more than 100 nm, no more than 80 nm, ^{obj} no more than 60 nm, no more than 50 nm, or no more than 30 nm. In some embodiments, the thin film may have a thickness of at least 1 nm, at least 5 nm or at least 10 nm. In some embodiments, the thin film may have a thickness of 1 nm to 100 nm, 5 nm to 80 nm, or 10 nm to 60 nm., 3 nm to 80 nm, 3 nm to 60 nm, 3 nm to 50 nm, 3 nm to 30 nm, or 3 nm to 20 nm.

A substrate transport mechanism 151 of system 100 includes a carriage comprising multiple turning guides for guiding substrate 114, including a set of first support roller 152 and a set of second support roller 152a (not shown in FIG. 1) spaced apart along precursor zone 128. Substrate transport mechanism 151 may further include a set of idler rollers 154 that can be used to support the substrate during a change in the direction of motion of the substrate 114.

System 100 may further include a substrate cooling system 156 to cool the substrate after the substrate 114 exits ALD coating system 126. System 100 may further include drum 158 for receiving and moving substrate 114.. System 100 can include a winder roller 164 for receiving coated substrate 114 and coiling the substrate 114 into a take-up roll.

System 100 may further include a vapor processing system. The vapor processing system can be any suitable vapor processing system, for example, a vapor source for producing a vapor and transferring the vapor.

Suitable substrates 114 for use in the system and method described herein include flexible materials capable of roll-to-roll processing, such as paper, polymeric materials, metal foils, and combinations thereof. Suitable polymeric substrates include various polyolefins, e.g. polypropylene, various polyesters (e.g. polyethylene terephthalate, fluorene polyester, polyethylene terephthalate glycol), polymethylmethacrylate and other polymers such as polyethylene naphthalate, polycarbonate, polymethylmethacrylate, polyethersulphone, polyestercarbonate, polyetherimide, polyarylate, polyimide, vinyls, cellulose acetates, cyclic olefin (co)polymers and fluoropolymers.

Suitable first precursor 132 and second precursor 134 can include those described in U.S. Pub. No. 2014/0242736. Non-limiting examples of first precursor 132 can include non-hydroxylated silicon-containing precursors including compounds such as tris(dimethylamino)silane (SiH[N(CH₃)₂]₃); tetra(dimethylamino)silane (Si[N(CH₃)₂]₄; bis(tertiary-butylamino)silane (SiH₂[HNC(CH₃)₃]₂); trisilylamine ((SiH₃)₃N) (available under the trade name TSA from L′Air Liquide S.A.); silanediamine, N,N,N′,N′-tetraethyl (SiH₂[N(C₂H₅)₂]₂) (available under the trade name SAM.24™ from L′Air Liquide S.A.); and hexakis(ethylamino)disilane (Si₂(NHC₂H₅)₆) (available under the trade name AHEAD™ from L′Air Liquide S.A.). Non-limiting examples of second precursor 134 can include metal-containing precursors, for example, metal halide compounds (e.g., titanium tetrachloride, tetrakis(dimethyamino)tin(TDMASn), zirconium tert-butoxide, Titanium Tetraisopropoxide, or TiCl₄) and metalorganic compounds (e.g., diethylzinc ((DEZ) or Zn(C₂H₅)₂) and trimethylaluminum (TMA)).

### EXAMPLES

### Materials

| | |
|---|---|
| Abbreviation | Description and Source |
| PET | Polyethylene terephthalate, 0.127 mm, commercially available as MELINEX ST505, obtained from DuPont Teijin Films™ (Chester, VA) |
| TTIP | Titanium (IV) tetraisopropoxide (CAS No. 546-68-9), 97%, obtained from Sigma-Aldrich (St. Louis, MO) |
| N₂ | Nitrogen (CAS No. 7727-37-9), > 99.998% from a refrigerated liquid source, filtered and dried through a compressed gas drier (DRIERITE DR50207), obtained from Praxair, Inc. (Danbury, CT) |
| N₂O | Nitrous Oxide (CAS No. 10024-97-2), research grade 99.999%, obtained from Matheson Gas (Irving, TX) |

### Coating Equipment

The coatings were deposited in a vacuum coater schematically shown in FIG. 1 which is similar to the coater described in U.S. Pat. Application Publication. US20190112711A1 (Lyons et al.). Note that additional dividers were added to create zones between Precursor 132, 134 and Compound 136 to create a new zone XXX where the precursor and reactive species are allowed to mix in a controlled manner. The entire system including the deposition zone was contained in an outer shell within which both the pressure and the gas atmosphere was controlled.

### Test Methods

### Method for Ellipsometry

The deposited films were characterized by spectroscopic ellipsometry over a wavelength range of 381 - 893 nm using an Alpha-SE spectroscopic ellipsometer obtained from J.A. Woolam Company, Lincoln, NE), . For films deposited on PET, prior to measurement the backside of the polymeric substrate was abraded with 3M™ Wetordry™ Sandpaper, 1000 Grit (available from 3M Company, Saint Paul, MN) to scatter the light and suppress back surface reflections such that anisotropic effects from the PET are minimized, as described in J.N. Hilfiker, B. Pietz, et al., Spectroscopic ellipsometry characterization of coatings on biaxially anisotropic polymeric substrates, Appl. Surf. Sci. (2016). The sample was measured in “Standard” measurement mode and sample alignment. The deposited layer was modeled with Cauchy dispersion, including surface roughness where appropriate.

### Method for Scanning Electron Microscopy (SEM)

Imaging was done using a model HITACHI 4700 FE-SEM (obtained from Hitachi America, Ltd, Santa Clara, CA). Samples were prepared by removing sections from the desired areas and cutting across the area of interest with a razor blade after clamping opposite sides of sections between forceps. The cross sectioned portions of the samples were mounted on aluminum SEM stubs using conductive carbon tape with the cross sectioned area facing upward.

All samples were coated with a thin (<2 nm) layer of AuPd alloy by DC sputtering in a Bench Top Turbo Coater (obtained from Denton Vacuum, Moorestown, NJ) to reduce sample charging effects in the SEM. Examples

### Example 1

Example 1 sample was prepared on a vacuum coating system sas described above This system was threaded up with a substrate in the form of an indefinite length roll of PET substrate. The system was then pumped down to a pressure of less than 10 mtorr. 4 SLMs of N₂ was then introduced to the system to increase the pressure to about 100 mtorr, and the substrate was advanced at a constant line speed of 3 m/min, heated with infrared lamps to 65° C., and translated through the deposition chamber heated to 65° C. to dry the substrate prior to the deposition process. The deposition chamber was then heated to 100° C. prior to starting the deposition process. During the deposition process, the substrate was advanced at a constant line speed at 3 m/min. TTIP, loaded into a precursor bubbler source(s) enclosed in a heating jacket was heated to 80° C., and N₂ push gas was introduced at 300 sccm per source. The precursor delivery line connecting the heated source to the first and second zones was heated to 90° C. The TTIP was continuously delivered into the first and the second zones of the system. N₂O and N₂ process gas was introduced into, and split between, the fourth and fifth zones at flow rates of 3 and 10 SLM. 2.5 SLM N₂ was introduced outside of the deposition zone, with the total pressure inside the system about 1.05 torr. The plasma array was ignited and controlled at a power of 20 kW (AC, current density = 0.6 mA/cm²). The mixture of the reactive species, process gas, and precursor was removed from the fourth zone and the fifth zone with balanced draw. The web was translated through the deposition chamber forward and backward to reach the targeted thickness.

FIG. 2 shows the cross-sectional SEM image of Example 1.

### Example 2

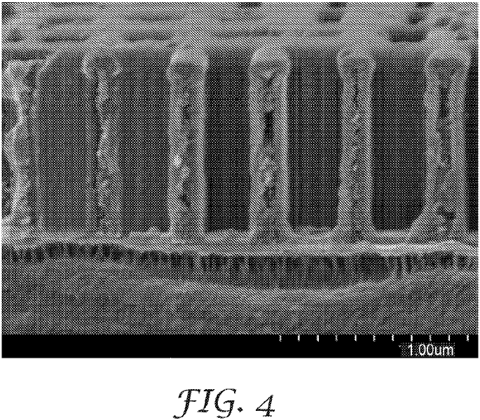

Example 2 was deposited in the same manner as Example 1, but with a line speed of 7.6 m/min. FIG. 3 shows the cross-sectional SEM image of Example 2.

### Example 3

Example 3 was deposited in the same manner as Example 1, but with a line speed of 0.6 m/min and plasma power of 20 kW. FIG. 4 shows the cross-sectional SEM image of Example 3.

The deposition rate and optical properties of the samples were determined using an ellipsometry as described above. Results are reported in Table 1, below.

TABLE 1

| | Example 1 | Example 2 | Example 3 | Comparative Example 1 | Comparative Example 2 |
|---|---|---|---|---|---|
| Total Thickness (nm) | 58 | 36 | 38 | 48 | 34 |
| Deposition Rate per Pass (nm/pass) | 14.6 | 9.1 | 38 | 4.8 | N/A |
| Refractive Index (@ 510 nm) | 2.36 | 2.35 | 2.34 | 2.35 | 1.85 |

### Comparative Examples

### Comparative Example 1

Comparative Example 1 was made on a vacuum coating system similar to that as described in U.S. Pat. Nos. 20190112711A1 (Lyons et al). This system was threaded up with a substrate in the form of an indefinite length roll of PET substrate. The system was then pumped down to a pressure of less than 10 mtorr. The PET substrate was then dried in a similar manner to that described in Example 1 before the deposition process. The deposition chamber was then heated to 100° C. prior to starting the deposition process. During the deposition process, the substrate was advanced at a line speed of 15.2 m/min for the first four passes through the system, and 30.5 m/min for the next six passes through the system. The deposited thickness per pass is expected to be independent of the line speed, per previous experiments and expected growth properties of atomic layer deposition processes. TTIP, loaded into a precursor bubbler source(s) enclosed in a heating jacket was heated to 80° C., and N₂ push gas was introduced at 300 sccm per source. The precursor delivery line connecting the heated source to the first and second zones was heated to 90° C. The TTIP was continuously delivered into the first and the second zones of the system. N₂O and N₂ process gas was introduced into, and split between, the fourth and fifth zones at flow rates of 4 and 15 SLM. 2.5 SLM N₂ was introduced outside of the deposition zone (sealing gas), with the total pressure inside the system about 1.4 torr. The plasma array was ignited and controlled at a power of 20 kW (AC, current density = 0.6 mA/cm²). The mixture of the reactive species, process gas, and precursor was removed from the first zone and the second zone with balanced draw. The web was translated through the deposition chamber forward and backward to reach the targeted thickness.

### Comparative Example 2

Comparative Example 2 was made in the same manner as Example 1, with the exception that the measured PET substrate was not translated through the system during the deposition process, but instead the sample was affixed in the fourth zone and thus not exposed directly to the precursor in the first or second zones, or directly to the plasma in the third zone. The sample was oriented in the same manner as the translated web.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A system, comprising,
a first zone into which a first precursor is introduced;
a second zone into which a second precursor is introduced;
a third zone between the first zone and the second zone and in which a reactive species is generated;
a fourth zone between the first zone and the third zone;
a fifth zone between the second zone and the third zone;
wherein a process gas is introduced into the fourth zone and the fifth zone;
wherein the reactive species and the first precursor is mixed in the fourth zone and the reactive species and the second precursor is mixed in the fifth zone; and
a substrate transport mechanism.

2. The system of claim 1, further comprising a vapor processing system comprising a vapor source for producing a vapor.

3. The system of claim 1, wherein a second surface of the substrate opposite the first surface thereof does not substantially contact the reactive species.

4. The system of claim 1, further comprising a substrate heating system to preheat the substrate.

5. The system of claim 1, further comprising a substrate cooling system to cool the substrate.

6. The system of claim 1, further comprising a substrate cooling system to cool the substrate.

7. The system of claim 1, wherein the mixture of the reactive species and the process gas is removed by a pump.

8. The system of claim 1, further comprising a radicals generator for supplying a reactive species to the third zone.

9. A method comprising:
transporting the substrate over the first and the second support rollers;
repeating the following sequence of steps to form a thin film on the substrate:
(a) exposing the substrate to a precursor;
(b) exposing the substrate to a mixture of a reactive species and a precursor; and
(c) exposing the substrate to a plasma and a reactive species.

10. The method of claim 9, further comprising (d) removing the mixture of the reactive species and the precursor.

11. The method of claim 9, wherein a second surface of the substrate opposite the first surface thereof does not substantially contact the reactive species.

12. The method of claim 9, wherein the reactive species is generated by applying energy to a compound.

13. (canceled)

14. The system of claim 1, wherein the first zone, the second zone and the third zone are bordered by an outer reaction chamber housing.
